(19) United States
(12) Patent Application Publication
(10) Pub. No.: US 2005/0120959 A1
(43) Pub. Date: Jun. 9, 2005

(54) Vacuum deposition device and pretreatment method for vacuum deposition

(75) Inventors: Yuji Isoda, Kanagawa (JP); Kohji Uchida, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/952,829

(22) Filed: Sep. 30, 2004

(30) Foreign Application Priority Data
Sep. 30, 2003 (JP) 2003-342262
Sep. 14, 2004 (JP) 2004-266940

(51) Int. Cl. C23C 16/00

(52) U.S. Cl. 118/726; 427/248.1

(57) ABSTRACT

The vacuum deposition device includes a vacuum deposition chamber, a vacuum evacuator for evacuating an inside of the chamber, an evaporating unit for evaporating one or more film forming materials in the chamber, a holding unit provided above the evaporating unit for holding a substrate for the vacuum deposition, and a preventing unit for preventing evaporated particles of the one or more materials from adhering to the substrate when the vacuum deposition is carried out at a pressure of 0.05 to 10 Pa. The pretreatment method for the vacuum deposition prepares the prevention unit in the chamber and melts the one or more materials by heating in the chamber at the pressure of 0.05 to 10 Pa while preventing the evaporated particles from adhering to the substrate by using the preventing unit.

### BACKGROUND OF THE INVENTION

The present invention relates to a vacuum deposition device and a pretreatment for vacuum deposition and, more specifically, to a vacuum deposition device by which a high-quality film is deposited even when deposition is carried out under medium vacuum and a pretreatment method for such vacuum deposition.

There are known a class of phosphors which accumulate a portion of applied radiations (e.g., X-rays, α-rays, β-rays, γ-rays, electron beam, and ultraviolet radiation) and which, upon stimulation by exciting light such as visible light, give off a burst of light emission in proportion to the accumulated energy. Such phosphors called “stimulable phosphors” are employed in medical and various other applications.

Known as an exemplary application is a radiation image information recording and reproducing system which employs a sheet (phosphor sheet) having a layer (to be referred to as “phosphor film” hereinafter) containing this stimulable phosphor. This phosphor sheet is called “radiation image converting panel (IP)” and is referred to as “phosphor sheet” in the following description. This system has already been commercialized by various companies including Fuji Photo Film Co., Ltd. which has marketed FCR (Fuji Computed Radiography).

In this system, radiation image information about a subject such as the human body is recorded on the phosphor sheet (more specifically, phosphor film). After that, the phosphor sheet is scanned two-dimensionally with exciting light such as laser light to produce stimulated emission. This stimulated emission is read photoelectrically to yield an image signal and an image reproduced on the basis of the image signal is output as a visible image, on a recording material such as a photographic material or on a display device such as CRT. The phosphor sheet which has been read is used repeatedly by erasing the residual image.

The above phosphor sheet is typically produced by: preparing a paint having the particles of a stimulable phosphor dispersed in a solvent containing a binder, etc.; applying the paint to a support in a sheet form that is made of glass, resin, or the like; and drying the applied coating to form a phosphor film.

Phosphor sheets are also known, which are made by forming a phosphor film on a support through methods of physical vapor deposition (vapor-phase film formation) such as vacuum deposition and sputtering (see, for example, JP 2003-172799 A).

The phosphor film formed on the support by evaporation has excellent characteristics. First, it contains less impurities since it is formed under vacuum; in addition, it is substantially free of any substances other than the stimulable phosphor, as exemplified by the binder, so it has high uniformity in performance and still assures very high luminous efficiency. This vacuum deposition method forms a phosphor film on the surface of a substrate by evaporating one or more film forming materials with one or more evaporators in an evaporating unit within a vacuum container.

To obtain excellent photostimulated luminescence characteristics, it is preferred that phosphor crystals should be grown to form a column (columnar crystal) having a sufficient height and good shape. To this end, it is known to be preferable that deposition be carried out at a lower degree of vacuum than usual. For instance, there is proposed a method of separating out needle-like crystals of a fluorescent substance by carrying out deposition at a relatively low degree of vacuum, i.e., 1 to 10 Pa (for example, US2001/0010831A1).

When vacuum deposition is carried out by using a vacuum deposition device, prior to vacuum deposition, a pretreatment must be carried out. This pretreatment is to store a film forming material in a crucible of an evaporator of an evaporating unit within a vacuum deposition device and heat the crucible while the pressure is reduced to a predetermined degree of vacuum to melt the film forming material. This pretreatment is carried out while the substrate such as a support is set in a holding unit of the vacuum deposition device, and then deposition is carried out after the pretreatment. The vapor of the film forming material, that is, fine particles of the film forming material are evaporated from the crucible during the pretreatment and diffused into the vacuum deposition chamber from the evaporator. Therefore, a shielding plate and a shutter are used to partition off the vacuum deposition chamber, and the shutter is closed to carry out the pretreatment while the particles of the film forming material are not diffused to the periphery of the holding unit from the evaporator.

To carry out deposition at a low degree of vacuum as described above, as molecules such as argon molecules float in the vacuum deposition chamber, the film forming material evaporated from the evaporator of the evaporating unit collides with these molecules and is prevented from reaching a position far away from the evaporator. As a result, the distance that the film forming material evaporated from the evaporator can reach is short. Therefore, to form a thick layer of the film forming material on the surface of the substrate S, the distance between the evaporator and the substrate must be made short as compared with that in a case where deposition is carried out under a high degree of vacuum.

However, at a low degree of vacuum, the film forming material evaporated from the evaporator easily adheres to the surface of the substrate at the time of the pretreatment which is carried out while the shutter is closed. That is, molecules such as argon molecules float in the vacuum chamber. Thus, when the film forming material is evaporated from the crucible of the evaporator during the pretreatment and diffused, it collides with molecules such as argon molecules floating around the evaporator and is diffused in a manner like Brownian motion to reach the edge and back of the shutter for blocking the top of the evaporator. Further, part of the film forming material is diffused to the periphery of the holding unit to adhere to the surface of the substrate held on the holding unit. When the subsequent deposition is carried out while the film forming material adheres to the surface of the substrate, the deposit adhering to the substrate at the time of pretreatment causes variations in film thickness and PSL (photo-stimulable luminescence) sensitivity. Since crystals constituting a deposited layer grow with the film forming material adhering to the surface as a nucleus, an abnormal crystal growth phenomenon called “hillock” occurs. In addition, the adhesive strength of the deposited layer to the surface of the substrate lowers with the result that the deposited layer easily peels off and greatly deteriorates. Documents including JP 2003-172799 A and US2001/0010831A1 fails to disclose the existence of the above problems.

### SUMMARY OF THE INVENTION

It is an object of the present invention, which has been made in view of the above situation, to provide a vapor deposition device capable of forming an excellent deposition layer and a pretreatment method of carrying out such vacuum deposition.

In order to attain the object described above, the invention provides a vacuum deposition device, comprising a vacuum deposition chamber, vacuum evacuation means for evacuating an inside of the vacuum deposition chamber, an evaporating unit for evaporating one or more film forming materials, the evaporating unit being provided in the vacuum deposition chamber, a holding unit for holding a substrate on which the one or more film forming materials are deposited, the holding unit being provided above the evaporating unit, and prevention means for preventing evaporated particles of the one or more film forming materials from adhering to the substrate held by the holding unit when vacuum deposition is carried out at a pressure of 0.05 to 10 Pa.

Preferably, the prevention means comprises a blocking member which is interposed between the evaporating unit and the holding unit so as to be movable between an opening position for opening an upper area located above the evaporating unit in the vacuum deposition chamber and a blocking position for blocking the upper area above the evaporating unit and which stops at the blocking position to block vapor flows of the one or more film forming materials flowing from the evaporating unit to the substrate, wherein the blocking member has a length W in a surface direction of the substrate which satisfies an expression (1):
W≧1.2×(length on an estimated plane+ΔX) (1)
wherein an estimated plane denotes a section obtained by cutting a cone whose bottom is a surface of the substrate and whose height is a distance between the evaporating unit and the substrate with a plane passing through a position at which the blocking member is provided and being parallel to the bottom of the cone, and ΔX denotes an amount of play in the surface direction of the substrate at the blocking position of the blocking member.

Preferably, the prevention means comprises a blocking member which is interposed between the evaporating unit and the holding unit so as to be movable between an opening position for opening an upper area located above the evaporating unit in the vacuum deposition chamber and a blocking position for blocking the upper area above the evaporating unit and which stops at the blocking position to block vapor flows of the one or more film forming materials flowing from the evaporating unit to the substrate, wherein the blocking member is variably provided at a position apart from one of the evaporating unit and the substrate by a distance d which satisfies an expression (2):
d≦M (2)
wherein M denotes a mean free path of the evaporated particles of the one or more film forming materials at a pretreatment pressure in the vacuum deposition.

Preferably, the prevention means comprises a blocking member which is interposed between the evaporating unit and the holding unit so as to be movable between an opening position for opening an upper area located above the evaporating unit in the vacuum deposition chamber and a blocking position for blocking the upper area above the evaporating unit and which stops at the blocking position to block vapor flows of the one or more film forming materials flowing from the evaporating unit to the substrate, wherein the blocking member has a length W in a surface direction of the substrate which satisfies an expression (1):
W≧1.2×(length on an estimated plane+ΔX) (1)
wherein an estimated plane denotes a section obtained by cutting a cone whose bottom is a surface of the substrate and whose height is a distance between the evaporating unit and the substrate with a plane passing through a position at which the blocking member is provided and being parallel to the bottom of the cone, and ΔX denotes an amount of play in the surface direction of the substrate at the blocking position of the blocking member, and wherein the blocking member is variably provided at a position apart from one of the evaporating unit and the substrate by a distance d which satisfies an expression (2):
d≦M (2)
wherein M denotes a mean free path of the evaporated particles of the one or more film forming materials at a pretreatment pressure in the vacuum deposition.

Preferably, the blocking member includes a plate-shaped portion facing the evaporating unit and one or more wall portions protruding downward from the plate-shaped portion.

Preferably, the prevention means further comprises one or more blocking members interposed between the evaporating unit and the substrate, and the blocking member and the one or more blocking members overlap each other when seen from a normal direction of the surface of the substrate.

Preferably, the evaporating unit has two or more evaporators which are installed beside each other in the surface direction of the substrate in the vacuum deposition chamber, and the prevention means further comprises one or more blocking members interposed between the evaporating unit and the substrate such that each blocking member is provided for each evaporator.

Preferably, the evaporating unit has two or more evaporators, and the blocking member is provided in one plane parallel to the surface of the substrate for the two or more evaporation sources such that the blocking member covers all of the two or more evaporators.

Preferably, the prevention means is separation means for locating the substrate in a space airtightly separated from a space where the evaporating unit exists.

Preferably, the separation means is a cover for airtightly enclosing the substrate held by the holding unit.

Preferably, the separation means includes a retreat chamber communicating with the vacuum deposition chamber, closing means for airtightly closing a communicating portion between the vacuum deposition chamber and the retreat chamber, and moving means for moving the substrate between the holding unit in the vacuum deposition chamber and the retreat chamber.

Preferably, the prevention means is means for moving the substrate away from the evaporating unit.

Preferably, a distance between the evaporating unit and the substrate held by the holding unit is 100 to 300 mm.

In order to attain the object described above, the invention also provides a pretreatment method for vacuum deposition comprising the step of preparing prevention means for preventing evaporated particles of one or more film forming materials from adhering to a substrate on which the one or more film forming materials are deposited in a vacuum deposition chamber, and melting the one or more film forming materials by heating in the vacuum deposition chamber at a pressure of 0.05 to 10 Pa while preventing the evaporated particles from adhering to the substrate for the vacuum deposition by using the prevention means.

Preferably, the prevention means is a blocking member which is interposed between an evaporating unit which evaporates the one or more film forming materials and is provided in the vacuum deposition chamber and a holding unit which holds the substrate and is provided above the evaporating unit so as to be movable between an opening position for opening an upper area located above the evaporating unit in the vacuum deposition chamber and a blocking position for blocking the upper area above the evaporating unit and which stops at the blocking position to block vapor flows of the one or more film forming materials flowing from the evaporating unit to the substrate, and wherein the blocking member has a length W in a surface direction of the substrate which satisfies an expression (1):
W≧1.2×(length on an estimated plane+ΔX) (1)
wherein an estimated plane denotes a section obtained by cutting a cone whose bottom is a surface of the substrate and whose height is a distance between the evaporating unit and the substrate with a plane passing through a position at which the blocking member is provided and being parallel to the bottom of the cone, and ΔX denotes an amount of play in the surface direction of the substrate at the blocking position of the blocking member.

Preferably, the prevention means is a blocking member which is interposed between an evaporating unit which evaporates the one or more film forming materials and is provided in the vacuum deposition chamber and a holding unit which holds the substrate and is provided above the evaporating unit so as to be movable between an opening position for opening an upper area located above the evaporating unit in the vacuum deposition chamber and a blocking position for blocking the upper area above the evaporating unit and which stops at the blocking position to block vapor flows of the one or more film forming materials flowing from the evaporating unit to the substrate, and wherein the blocking member is variably provided at a position apart from one of the evaporating unit and the substrate by a distance d which satisfies an expression (2):
d≦M (2)
wherein M denotes a mean free path of the evaporated particles of the one or more film forming materials at a pretreatment pressure in the vacuum deposition.

Preferably, the prevention means is a blocking member which is interposed between an evaporating unit which evaporates the one or more film forming materials and is provided in the vacuum deposition chamber and a holding unit which holds the substrate and is provided above the evaporating unit so as to be movable between an opening position for opening an upper area located above the evaporating unit in the vacuum deposition chamber and a blocking position for blocking the upper area above the evaporating unit and which stops at the blocking position to block vapor flows of the one or more film forming materials flowing from the evaporating unit to the substrate, and wherein the blocking member has a length W in a surface direction of the substrate which satisfies an expression (1):
W≧1.2×(length on an estimated plane+ΔX) (1)
wherein an estimated plane denotes a section obtained by cutting a cone whose bottom is a surface of the substrate and whose height is a distance between the evaporating unit and the substrate with a plane passing through a position at which the blocking member is provided and being parallel to the bottom of the cone, and ΔX denotes an amount of play in the surface direction of the substrate at the blocking position of the blocking member, and wherein the blocking member is variably provided at a position apart from one of the evaporating unit and the substrate by a distance d which satisfies an expression (2):
d≦M (2)
wherein M denotes a mean free path of the evaporated particles of the one or more film forming materials at a pretreatment pressure in the vacuum deposition.

Preferably, the blocking member includes a plate-shaped portion facing the evaporating unit and one or more wall portions protruding downward from the plate-shaped portion.

Preferably, the prevention means further comprises one or more blocking members interposed between the evaporating unit and the substrate, and the blocking member and the one or more blocking members overlap each other when seen from a normal direction of the surface of the substrate.

Preferably, the evaporating unit has two or more evaporators containing at least two evaporators for CsBr and EuBr₂, which are provided on respective predetermined planes parallel to the surface of the substrate in the vacuum deposition chamber, and the prevention means further comprises one or more blocking members interposed between the evaporating unit and the substrate such that each blocking member is provided for each evaporator. wherein two or more evaporating units containing at least CsBr and EuBr₂ are provided on respective predetermined planes parallel to the surface of the substrate in the vacuum deposition chamber and the blocking member is provided for each of the evaporating units.

Preferably, the evaporating unit has two or more evaporators containing at least two evaporators for CsBr and EuBr₂, and the blocking member is provided in one plane parallel to the surface of the substrate for the two or more evaporation sources such that the blocking member covers all of the two or more evaporators.

Preferably, the prevention means is separation means for locating the substrate in a space airtightly separated from a space where the evaporating unit exists.

Preferably, the separation means is a cover for airtightly enclosing the substrate held by the holding unit.

Preferably, the separation means includes a retreat chamber communicating with the vacuum deposition chamber, closing means for airtightly closing a communicating portion between the vacuum deposition chamber and the retreat chamber, and moving means for moving the substrate between the holding unit in the vacuum deposition chamber and the retreat chamber.

Preferably, the prevention means is means for moving the substrate away from the evaporating unit.

Preferably, a distance between the evaporating unit and the substrate held by the holding unit is 100 to 300 mm.

According to the present invention, there are provided a vacuum deposition device capable of forming an excellent deposition layer and a pretreatment method for carrying out such vacuum deposition.

This application claims priority on Japanese patent application No.2003-342262 and No.2004-266940, the entire contents of which are hereby incorporated by reference No.2003-342262. In addition, the entire contents of literatures cited in this specification are incorporated by reference.

### BRIEF DESCRIPTION OF THE DRAWINGS

In the accompanying drawings:

FIG. 1 is a schematic side view of the inside of a vacuum deposition device, showing a schematic structure of the vacuum deposition device according to an embodiment of the present invention;

FIG. 2 is a schematic partial side view of the device shown in FIG. 1 for explaining the position relationship among a turntable, substrate and evaporators;

FIG. 3A is a schematic longitudinal sectional view of the device shown in FIG. 1 for explaining the vertical position relationship and size relationship among the evaporator, substrate and shutter;

FIG. 3B shows the position relationship and size relationship in the substrate surface direction among the evaporator, substrate and shutter;

FIG. 4 is a schematic longitudinal sectional view of the device shown in FIG. 1 showing the arrangement of the evaporators, substrate and shutter and explaining how to take the estimated plane in the case of two-source vapor deposition;

FIG. 5 is a longitudinal sectional view of a first modification example of the present invention;

FIG. 6 is a longitudinal sectional view of a second modification example of the present invention;

FIGS. 7A, 7B and 7C are longitudinal sectional views showing other examples of the shutters according to the present invention;

FIGS. 8A and 8B are each a schematic side view showing a schematic structure of the vacuum deposition device according to another embodiment of the present invention;

FIG. 9 is a schematic plan view showing a schematic structure of the vacuum deposition device according to still another embodiment of the present invention;

FIG. 10 is a graph showing the relationship between the distance between the evaporator in the evaporating unit and the shutter and the characteristic properties of a phosphor film deposited on the surface of the substrate; and

FIG. 11 is a graph showing the relationship between the size (diameter) of the shutter and the characteristic properties of a phosphor film deposited on the surface of the substrate.

### DETAILED DESCRIPTION OF THE PREFFERRED EMBODIMENTS

The vacuum deposition device and the pretreatment method for the vacuum deposition according to the present invention will be described below in detail with reference to the preferred embodiments shown in the accompanying drawings.

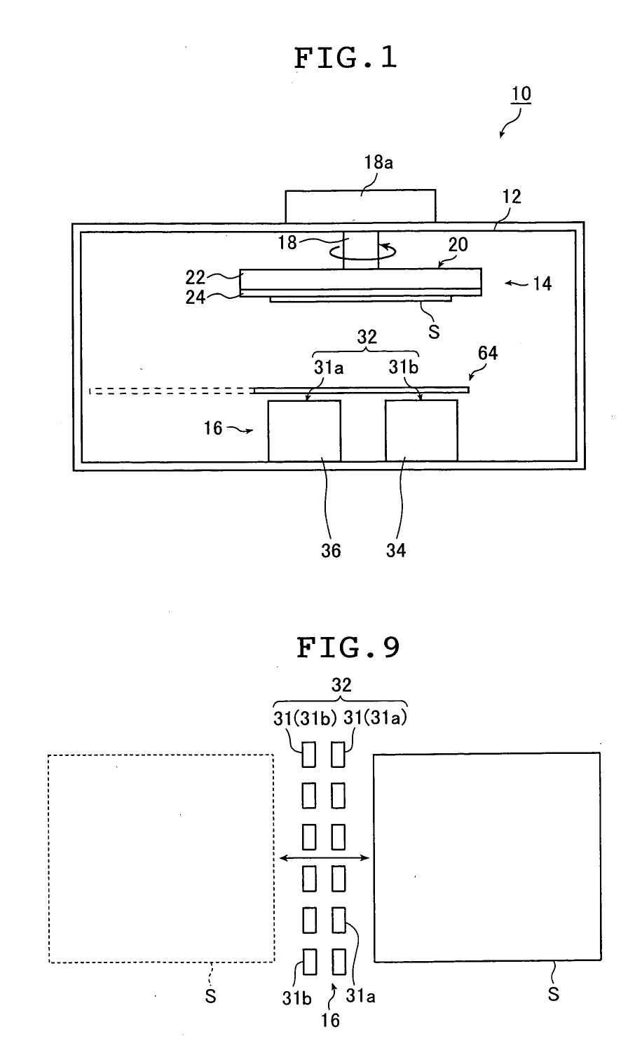

FIG. 1 is a schematic side view of the inside of a vacuum deposition device 10 (to be simply referred to as “device” hereinafter) according to an embodiment of the present invention, showing a schematic structure of the vacuum deposition device 10. The device 10 according to this embodiment is used to manufacture a phosphor sheet by forming a stimulable phosphor film on the surface of a sheet-like glass substrate (to be simply referred to as “substrate” hereinafter) S as a substrate by two-source vapor deposition.

The device 10 according to this embodiment is a so-called substrate rotation type vacuum deposition device which basically includes a vacuum chamber 12 as a vacuum deposition chamber, a substrate holding and rotating mechanism 14 as a holding unit (holding means), and a heating evaporating section 16 as an evaporating unit. As will be described hereinafter, the device 10 according to this embodiment may include a thermal shielding plate (not shown) for blocking out radiation heat from the heating evaporating section 16 toward the substrate in the vacuum chamber 12.

The device 10 according to this embodiment has a vacuum pump (evacuating means) (not shown) for evacuating the inside of the vacuum chamber 12 to achieve a predetermined degree of vacuum besides the above elements and is connected to gas introduction means for introducing a gas to be described hereinafter into the vacuum chamber 12.

The device 10 according to this embodiment carries out two-source vacuum deposition of cesium bromide (CsBr) and europium bromide (EuBr₂) as film forming materials to form a phosphor film of CsBr:Eu as a stimulable phosphor on the glass substrate S to manufacture a phosphor sheet.

The stimulable phosphor is not limited to the above CsBr:Eu and various materials can be used. A stimulable phosphor which gives off light having a wavelength of 300 nm to 500 nm upon stimulation by excitation light having a wavelength of 400 to 900 nm is preferably used.

Various materials can be used as the stimulable phosphor constituting the phosphor film. Preferred examples of the stimulable phosphor are given below.

Stimulable phosphors disclosed in U.S. Pat. No. 3,859,527 are “SrS:Ce, Sm”, “SrS:Eu, Sm”, “ThO₂:Er”, and “La₂O₂S:Eu, Sm”.

JP 55-12142 A discloses “ZnS:Cu, Pb”, “BaO.xAl₂O₃:Eu (0.8≦x≦10)”, and stimulable phosphors represented by the general formula “M^{II}O.xSiO₂:A”. In this formula, M^{II} is at least one element selected from the group consisting of Mg, Ca, Sr, Zn, Cd, and Ba, A is at least one element selected from the group consisting of Ce, Tb, Eu, Tm, Pb, Tl, Bi, and Mn, and 0.5≦x≦2.5.

Stimulable phosphors represented by the general formula “LnOX:xA” are disclosed by JP 55-12144 A. In this formula, Ln is at least one element selected from the group consisting of La, Y, Gd, and Lu, X is at least one element selected from Cl and Br, A is at least one element selected from Ce and Tb, and 0≦x≦0.1.

Stimulable phosphors represented by the general formula “(Ba₁₋ₓ, M²⁺ₓ)FX:yA” are disclosed by JP 55-12145 A. In this formula, M²⁺ is at least one element selected from the group consisting of Mg, Ca, Sr, Zn, and Cd, X is at least one element selected from Cl, Br, and I, A is at least one element selected from Eu, Tb, Ce, Tm, Dy, Pr, Ho, Nd, Yb, and Er, 0≦x≦0.6, and 0≦y≦0.2.

JP 57-14825 A discloses the following stimulable phosphors. That is, the stimulable phosphors are represented by the general formula “xM₃(PO₄)₂.NX₂:yA” or “M₃(PO₄)₂.yA”. In this formula, M and N are each at least one element selected from the group consisting of Mg, Ca, Sr, Ba, Zn, and Cd, X is at least one element selected from F, Cl, Br, and I, A is at least one element selected from Eu, Tb, Ce, Tm, Dy, Pr, Ho, Nd, Yb, Er, Sb, Tl, Mn, and Sn, 0≦x≦6, and 0≦y≦1.

Stimulable phosphors are represented by the general formula “nReX₃.mAX′₂:xEu” or “nReX₃.mAX′₂:xEu, ySm”. In this formula, Re is at least one element selected from the group consisting of La, Gd, Y, and Lu, A is at least one element selected from Ba, Sr, and Ca, X and X′ are each at least one element selected from F, Cl, and Br, 1×10⁻⁴<x<3×10⁻¹, 1×10⁻⁴<y<1×10⁻¹, and 1×10⁻³<n/m<7×10⁻¹.

Alkali halide-based stimulable phosphors are represented by the general formula “M^{I}X.aM^{II}X′₂.bM^{III}X″₃:cA”. In this formula, M^{I} represents at least one element selected from the group consisting of Li, Na, K, Rb, and Cs. M^{II} represents at least one divalent metal selected from the group consisting of Be, Mg, Ca, Sr, Ba, Zn, Cd, Cu, and Ni. M^{III} represents at least one trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one element selected from the group consisting of F, Cl, Br, and I. A represents at least one element selected from the group consisting of Eu, Tb, Ce, Tm, Dy, Pr, Ho, Nd, Yb, Er, Gd, Lu, Sm, Y, Tl, Na, Ag, Cu, Bi, and Mg, 0≦a<0.5, 0≦b<0.5, and 0≦c<0.2.

Stimulable phosphors are represented by the general formula “(Ba₁₋ₓ, M^{II}ₓ)F₂.aBaX₂:yEu, zA” disclosed by JP 56-116777 A. In this formula, M^{II} is at least one element selected from the group consisting of Be, Mg, Ca, Sr, Zn, and Cd, X is at least one element selected from Ci, Br, and I, A is at least one element selected from Zr and Sc, 0.5≦a≦1.25, 0≦x≦1, 1×10⁻⁶≦y≦2×10⁻¹ and 0≦z≦1×10⁻².

Stimulable phosphors represented by the general formula “M^{III}OX:xCe” are disclosed by JP 58-69281 A. In this formula, M^{III} is at least one trivalent metal selected from the group consisting of Pr, Nd, Pm, Sm, Eu, Tb, Dy, Ho, Er, Tm, Yb, and Bi, X is at least one element selected from Cl and Br, and 0≦x≦0.1.

Stimulable phosphors represented by the general formula “Ba₁₋ₓMₐLₐFX:yEu²⁺” are disclosed by JP 58-206678 A. In this formula, M is at least one element selected from the group consisting of Li, Na, K, Rb, and Cs, L is at least one trivalent metal selected from the group consisting of Sc, Y, La, Ce, Pr, Nd, Pm, Sm, Gd, Tb, Dy, Ho, Er, Tm, Yb, Lu, Al, Ga, In, and Tl, X is at least one element selected from Cl, Br, and I, 1×10⁻²≦x≦0.5, 0≦y≦0.1, and a is x/2.

Stimulable phosphors represented by the general formula “M^{II}FX.aM^{I}X′.bM′^{II}X″₂.cM^{III}X₃.xA:yEu²⁺” are disclosed by JP 59-75200 A. In this formula, M^{II} is at least one element selected from the group consisting of Ba, Sr, and Ca, M^{I} is at least one element selected from Li, Na, K, Rb, and Cs, M′^{II} is at least one divalent metal selected from Be and Mg, M^{III} is at least one trivalent metal selected from the group consisting of Al, Ga, In, and Tl, A is a metal oxide, X, X′, and X″ are each one element selected from the group consisting of F, Cl, Br, and I, 0≦a≦2, 0≦b≦1×10⁻², 0≦c≦1×10⁻², and a+b+c≧10⁻⁶, 0<x≦0.5, and 0<y≦0.2.

Alkali halide-based stimulable phosphors disclosed by JP 57-148285 A are preferred because they have excellent photostimulated luminescence characteristics and the effect of the present invention is advantageously obtained. Alkali halide-based stimulable phosphors in which M^{I} contains at least Cs, X contains at least Br, and A is Eu or Bi are more preferred, and stimulable phosphors represented by the general formula “CsBr:Eu” are particularly preferred.

In the present invention, a phosphor film made of the above stimulable phosphor is formed by vacuum deposition.

In particular, multi-source vacuum deposition for evaporating a phosphor component material and an activator component material by heating them separately is particularly preferred. For example, to form the above CsBr:Eu phosphor film, multi-source vacuum deposition for evaporating cesium bromide (CsBr) as the phosphor component material and europium bromide (EuBr₂) as the activator component material by heating separately is preferred.

Heating methods for vacuum deposition are not particularly limited. For example, it may be electron beam heating using an electron gun or resistance heating. Further, to carry out multi-source vacuum deposition, the same heating means (for example, electron beam heating) may be used to evaporate all the materials, or electron beam heating may be used to evaporate the phosphor component material and resistance heating may be used to evaporate a trace amount of the activator component material.

In the device 10 according to this embodiment, the ultimate degree of vacuum in the vacuum chamber 12 is preferably about 1×10⁻⁵ Pa to 1×10⁻² Pa. The pressure of moisture in the atmosphere of the device is preferably set at 7.0×10⁻³ Pa or less by using a diffusion pump (or turbo-molecular pump). An inert gas such as Ar gas, Ne gas, or N₂ gas is introduced under evacuation to control the degree of vacuum to about 0.05 to 10 Pa, preferably about 0.5 to 1.5 Pa.

The deposition condition (so-called “medium vacuum condition”) that the degree of vacuum is set at about 0.05 to 10 Pa, preferably about 0.5 to 1.5 Pa by introducing an inert gas such as Ar gas, Ne gas, or N₂ gas while the above condition is maintained can provide a good shape to the column of the formed stimulable phosphor (columnar structure). As a result, the X-ray characteristics can be improved. In particular, image nonuniformity (structure) of the formed stimulable phosphor can be alleviated.

The term “image nonuniformity (structure)” means (A) the nonuniformity of an X-ray image when an X-ray photo is taken using a phosphor sheet (deposition IP/radiation image converting panel) manufactured by forming a phosphor film on the surface of a substrate by vacuum deposition and (B) the columnarity, that is, the perfection of the columnar structure of a phosphor crystal constituting a phosphor film formed on the surface of the substrate of a phosphor sheet (specifically, the height of the aspect ratio of a columnar crystal, space uniformity, the existence of hillock).

As will be described hereinafter, out of those, the image nonuniformity is particularly important in the vacuum deposition device according to this embodiment. The image nonuniformity (A) is mainly caused by nonuniformity in the thickness of the phosphor film formed on the surface of the substrate of the phosphor sheet and a phenomenon that even when an X-ray having uniform intensity is applied to the entire surface of the phosphor sheet, the obtained X-ray image has a portion which appears to be light and a portion which appears to be dark. More specifically, this image nonuniformity is caused by three factors: (1) nonuniformity in the concentration of Eu; (2) nonuniformity in the thickness of the phosphor film formed on the surface of the substrate; and (3) columnarity. The thick portion of the phosphor film has a large amount of the absorbed X-ray and appears to be light on the X-ray image and the thin portion of the phosphor film has a small amount of the absorbed X-ray and appears to be dark on the X-ray image. The image nonuniformity can be alleviated by forming a film under the above conditions.

The perfection of the columnar structure of the phosphor crystal is evaluated based on three factors as indices: (a) high aspect ratio of each crystal (high aspect ratio); (b) uniform spacing between adjacent columnar crystals (uniform spacing); and (c) observation of no hillock because phosphor crystals constituting the phosphor film grow in a direction substantially perpendicular to the surface of the substrate (absence of hillock). When multi-source vacuum deposition is carried out, the evaporation speeds of the main component and the activator component are controlled to ensure that the weight ratio of these components falls within the target range.

The phosphor film may be heated at 50 to 400° C. by heating the substrate during film formation.

Further, the thickness of the phosphor film to be formed is not particularly limited but preferably 10 to 1,000 μm, particularly preferably 20 to 800 μm.

The vacuum chamber 12 is a known vacuum chamber (bell jar, vacuum tank) which is made of iron, stainless steel, or aluminum and used in a vacuum deposition device. In the illustrated embodiment, the substrate holding and rotating mechanism 14 and the heating evaporating section 16 are installed in the upper and lower parts of the vacuum chamber 12, respectively. Only one heating evaporating section 16 is used in this embodiment. It is needless to say that a plurality of heating evaporating units 16 may be used.

As described above, the vacuum chamber 12 is connected to a vacuum pump (not shown) as evacuation means. The vacuum pump is not particularly limited and various vacuum pumps used in a vacuum deposition device may be used if they can achieve a required ultimate degree of vacuum. For example, an oil diffusion pump, cryopump, or turbo-molecular pump may be used, and a cryocoil or the like may be used in combination with the vacuum pump.

The substrate holding and rotating mechanism 14 turns while holding the substrate S and includes a rotary shaft 18 to be engaged with a rotation drive source (motor) 18a and a turntable 20. The turntable 20 is a disk consisting of an upper body 22 and a lower sheathed heater 24 (on the heating evaporating section 16 side), and the rotary shaft 18 engaged with the above motor 18a is fixed to the center of the disk. The turntable 20 holds the substrate S on its undersurface (undersurface of the sheathed heater 24) on the heating evaporating section 16 side, that is, the evaporation position of the film forming materials and is turned at a predetermined speed by the rotary shaft 18. The sheathed heater 24 heats the substrate S on which a film is formed from its rear side (side opposite to the film forming side).

The substrate S which can be used herein is not particularly limited and various substrates used in phosphor panels may be used. Examples of the substrate S include: plastic films such as a cellulose acetate film, polyester film, polyethylene terephthalate film, polyamide film, polyimide film, triacetate film, and polycarbonate film; glass plates made of quartz glass, non-alkali glass, soda glass, heat resistant glass (Pyrex™, etc.), and the like; metal sheets such as an aluminum sheet, iron sheet, copper sheet and chromium sheet; and metal sheets having a metal oxide coating layer.

The heating evaporating section 16 is installed in the lower part of the vacuum chamber 12. As described above, the illustrated device 10 carries out two-source vacuum deposition for evaporating cesium bride (CsBr) and europium bromide (EuBr₂) as film forming materials by heating separately. Therefore, the heating evaporating section 16 has a cesium evaporator (to be referred to as “Cs evaporator” hereinafter) 31a and a europium evaporator (to be referred to as “Eu evaporator” hereinafter) 31b as an evaporating unit 32. Further, a shutter 64 is provided over the evaporating unit 32.

The Eu evaporator 31b has the function of evaporating europium bromide (activator material) in an evaporation position (crucible) by resistance heating with a resistance heater 34.

The Cs evaporator 31a has the function of evaporating cesium bromide (main crystal material) in an evaporating position (crucible) by resistance heating with a resistance heater 36.

In this embodiment, the means for evaporating europium bromide and cesium bromide is not particularly limited and any heating evaporation means may be used if it can provide a sufficiently high film forming speed for a phosphor film essentially composed of a phosphor and having a thickness of more than 200 μm. Each evaporation position is provided with material feed means (not shown) for feeding each material.

In the manufacture of a phosphor sheet, an extremely small amount of an activator is used as compared with a phosphor, and the control of the components of the phosphor film is important. Therefore, it is preferred to form a film on the substrate S from a mixed vapor prepared by generating vapors of the phosphor and the activator as film forming materials separately and fully mixing them together. To this end, the evaporation positions of the phosphor material and the activator material are preferably arranged close to each other. As the evaporation positions of those materials are closer to each other, a higher-quality phosphor film containing the activator dispersed therein uniformly can be formed. In addition, as the evaporation positions are closer to each other, an area for mixing together the two vapors can be made wider, thereby making it possible to improve the use efficiency of the materials.

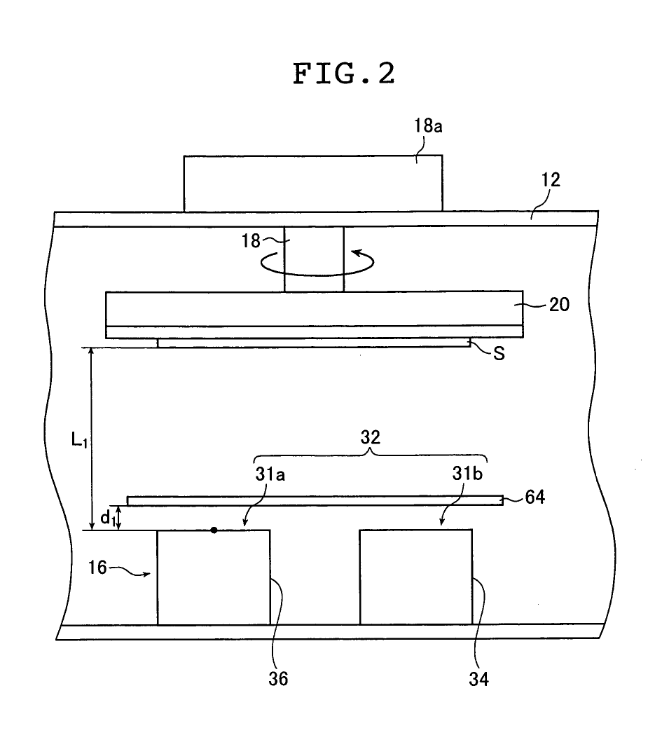

A description is subsequently given of the relationship among the evaporating unit 32, the substrate S, and the shutter 64 as a blocking member in the vacuum chamber 12 of the vacuum deposition device 10 of this embodiment. FIG. 2 is a side view for explaining the position relationship among the turntable 20, substrate S, Cs evaporator 31a, and Eu evaporator 31b in the vacuum chamber 12 of the device 10 of this embodiment.

The blocking member, that is, the shutter 64 serves as prevention means for preventing evaporated particles from adhering to the substrate S upon the vacuum deposition under medium vacuum (0.05 to 10 Pa).

As shown in FIG. 1 and FIG. 2, the evaporating unit 32, that is, the Eu evaporator 31b and the Cs evaporator 31a are installed in the lower part of the vacuum chamber 12, the turntable 20 is installed in the upper part of the vacuum chamber 12, and the shutter 64 is interposed between the Eu evaporator 31b/Cs evaporator 31a and the turntable 20.

In the vacuum deposition device 10 of this embodiment, the distance L₁ between the evaporating unit 32 (that is, Eu evaporator 31b and Cs evaporator 31a) and the substrate S is preferably 100 to 300 mm. When the distance L₁ between the evaporating unit 32 and the substrate S is smaller than 100 mm, it is difficult to form a phosphor film on the surface of the substrate S uniformly. When the distance L₁ between the evaporating unit 32 and the substrate S is larger than 300 mm, particles evaporated from the evaporating unit 32 are blocked by molecules such as argon molecules existent in the vacuum chamber and cannot reach the substrate S under so-called “medium vacuum” where the above high-quality phosphor film is obtained, thereby making it impossible to form a deposited film.

As shown in FIG. 2, the evaporating unit 32 are installed below the substrate S held by the turntable 20 in the vacuum deposition device 10, the distance L₁ between the substrate S and the evaporating unit 32 is 100 to 300 mm, and the shutter 64 is interposed between the turntable 20 and the evaporating unit 32. This shutter 64 is a plate-like member made of a metal such as stainless steel and the shutter 64 of this embodiment has a disk-like shape. The shutter 64 having a shape other than the disk-like shape may be a square or rectangular shutter. This shutter 64 has a length W, that is, a diameter in the surface direction of the substrate S, which will be described later.

There is no particular limitation on the position of the shutter 64 (distance d between the shutter 64 and the evaporating unit 32, or distance d between the shutter 64 and the substrate). However, the distance preferably satisfies the following expression (2):
d≦M (2)
where M is mean free path of film forming material particles at a pretreatment pressure before vacuum deposition is carried out under medium vacuum.

Stated more specifically, in the device 10 of this embodiment, the distance d₁ between the shutter 64 and the evaporating unit 32 is 10 mm. The distance d₁ between the evaporating unit 32 and the shutter 64 is preferably 3 to 200 mm, more preferably 3 to 100 mm. When the distance d₁ between the evaporating unit 32 and the shutter 64 is smaller than 3 mm, evaporated particles adhere to the shutter 64, making it impossible to open or close the shutter 64. When the distance d₁ between the evaporating unit 32 and the shutter 64 is larger than 200 mm, particles evaporated from the evaporating unit 32 do not reach the substrate S.

The installation position of the shutter 64 may be close to the substrate S as a position other than the position close to the evaporating unit 32. More specifically, the shutter may be installed at a position apart from the substrate S by a distance shorter than the mean free path of film forming material particles at a pretreatment pressure, for example, 0.1 Pa. In this case, to be specific, the distance between the substrate S and the shutter 64 is preferably 0.1 to 15 mm. When the distance between the substrate S and the shutter 64 is smaller than 0.1 mm, it is fairly possible that the shutter 64 contacts the substrate S and damages the substrate S at the time of opening and closing the shutter 64. When the distance between the substrate S and the shutter 64 is larger than 15 mm, it is fairly possible that particles evaporated and moved from the evaporating unit 32 reach the rear surface (surface opposed to the substrate S) of the shutter 64 and adhere to the surface of the substrate S.

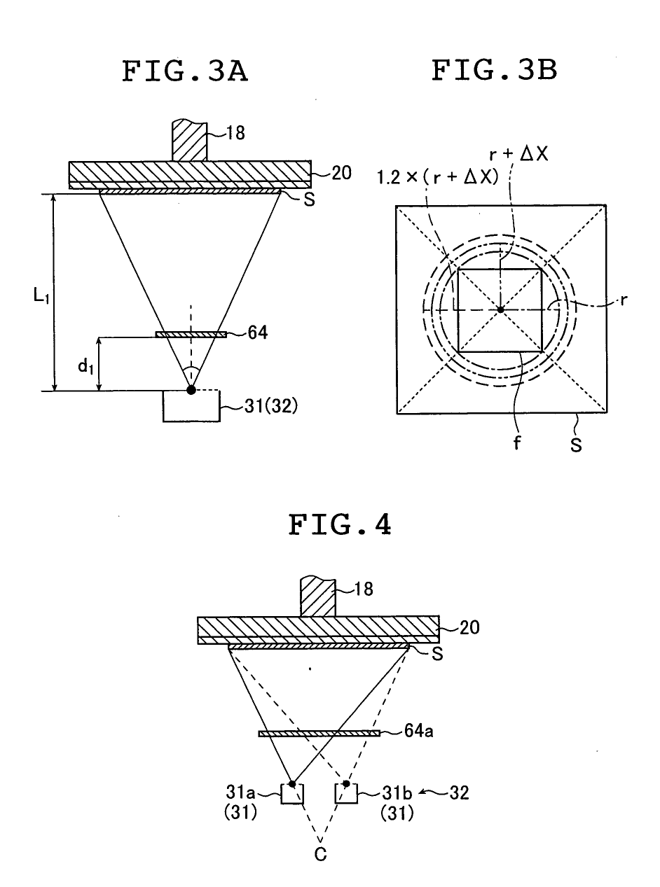

A description is subsequently given of the size, specifically, length in the substrate S surface direction of the shutter 64. The length in the substrate S surface direction of the shutter 64 is based on the length of the “estimated plane” which will be described hereinafter. The estimated plane differs according to circumstances. Therefore, (although the device 10 of this embodiment is provided with the evaporating unit having two evaporators for two-source vacuum deposition), for the simplification of its explanation, a case where one-source vacuum deposition, that is, the evaporating unit having only one evaporator is used will be described first and then the estimated plane in the case of two-source vacuum deposition will be described. FIGS. 3A and 3B are schematic longitudinal sectional views for explaining the position relationship and the size relationship among the evaporator 31 in the evaporating unit 32, the substrate S, and the shutter 64 in the vertical direction and substrate surface direction, respectively.

In the present invention, the shutter 64 has a length W which satisfies the condition represented by the following expression (1) in the surface direction of the substrate S.
W≧1.2×(length on estimated plane+ΔX) (1)

The expression “estimated plane” denotes a section obtained by cutting a conical or polygonal pyramidal solid whose apex is the evaporator 31 in the evaporating unit 32 (for example, its central position), whose bottom is the surface of the substrate S, and whose height is the distance L₁ between the evaporator 31 and the substrate S with a plane parallel to the surface of the substrate S and passing the installation position of the shutter 64, that is, a point away from the apex in the direction of a perpendicular line to the bottom from the apex of the above solid by a distance d₁ (distance from the evaporator to the blocking member).

When plural substrates S are used, the estimated plane can be set by determining a minimal plane including the surfaces of all the substrates S and assuming that the set minimal plane is the substrate surface.

A description is subsequently given of how to take the estimated plane in the case of two-source vacuum deposition. In the device of this embodiment, as shown in FIG. 1 and FIG. 2, a plurality of evaporators, for example, two evaporators as the evaporating unit are arranged on a plane parallel to the surface of the substrate S. When two evaporators as the evaporating unit are arranged, as shown in FIG. 4, a plane parallel to a sheet passing three points, i.e., the positions of the two evaporators 31a and 31b and the center of the substrate S is considered. The intersection point C between two straight lines connecting the positions of the two evaporators 31a and 31b and both the ends of the substrate S is obtained. A cone having an apex which is the intersection C and a bottom which is the surface of the substrate S is considered. The cut section obtained by cutting this cone with a plane passing the installation position of the shutter 64a and parallel to the bottom (surface of the substrate S) is taken as the estimated plane.

When there are three or more evaporation sources and the evaporation sources have a significant area (area of a plane opposed to the substrate) or are linear, the smallest circle (to be referred to as “first circle” hereinafter) including all the evaporation sources is considered. The smallest circle (to be referred to as “second circle” hereinafter) including the whole area where the substrate S can move is considered. In this state, a cone whose side passes the first circle and whose bottom is the second circle is considered. The section obtained by cutting this cone with a plane passing the installation position of the shutter 64 and parallel to the bottom of the cone (second circle) is taken as the estimated plane.

In this embodiment, one shutter 64 is provided for plural evaporators (Cs evaporator 31a and Eu evaporator 31b) corresponding to the two-source vacuum deposition.

When one shutter 64 is provided for more than one evaporator 31 (31a, 31b, . . . ) in the evaporating unit 32 as in this embodiment, the estimated plane can be set by detecting provisional estimated planes for the respective evaporators 31 in the evaporating unit 32 and determining a minimal circle, ellipse, square, rectangle or the like including the provisional estimated planes of all the evaporators 31. To be more specific, the estimated plane can be set by detecting provisional estimated planes for the Cs evaporator 31a and the Eu evaporator 31b and determining a minimal circle, rectangle or the like including both the provisional estimated planes, as shown in FIG. 4.

Any shapes including circle, ellipse, square and rectangle can be arbitrarily selected, but it is advantageous to select a shape so that the area of the estimated plane can be small in terms of the size of the shutter 64.

The amount of play ΔX in the surface direction of the substrate S at the blocking position of the shutter 64 which is another standard for determining the length in the substrate S surface direction of the shutter 64 will be described hereinunder. ΔX represents the amount of play of the shutter 64 in the surface direction of the substrate S (horizontal direction in FIG. 1) when the shutter 64 is stopped at a blocking position. The expression “amount of play” refers to a mechanical margin in the surface direction of the substrate S when the shutter 64 is moved to the blocking position, that is, a position above the evaporating unit 32 (evaporator or evaporators 31) to cover the evaporating unit 32 (evaporator or evaporators 31) and stopped at the blocking position for blocking the opening of the evaporating unit 32 (evaporator or evaporators 31). That is, the expression refers to the size of so-called “play”, the range in the surface direction of the substrate S of the position able to be taken by the periphery of the shutter 64 in a blocking state. For example, if the blocking position of the shutter 64 changes within a range of ±1 mm in the surface direction of the substrate S when the position of the shutter 64 is measured based on a fixed point in the vacuum deposition device 10, for example, the position of the evaporating unit 32 (evaporator or evaporators 31) and the shutter 64 is moved between the blocking position and the non-blocking position a predetermined number of times, the amount of play ΔX in the surface direction of the substrate S becomes 1 mm.

The direction of this “play” is a direction substantially perpendicular to the flow direction of particles evaporated from the evaporator, specifically, the surface direction (horizontal direction in FIG. 1) of the substrate S. The play of the shutter 64 may include not only play in the moving direction of the shutter 64 but also play in other direction.

The value obtained by multiplying the sum of the length of the estimated plane obtained as described above and the amount of play ΔX in the surface direction of the substrate S at the blocking position of the shutter 64 by 1.2 is the minimum value of the length of the shutter 64. The shutter 64 must have a length W equal to or larger than this value. In other words, the length W of the shutter satisfies the expression (1): W≧1.2×(length on estimated plane+ΔX).

To be more specific, when the shutter 64 is circular, a minimal circle including the estimated plane f is set, the amount of play ΔX is added to the diameter r of this circle (r+ΔX), and the value obtained by addition is multiplied by 1.2 ((r+ΔX)×1.2). The circular shutter 64 need only have a diameter which is equal to or larger than the resulting value (see FIG. 3B).

When the shutter 64 is elliptical, a minimal ellipse including the estimated plane is set. The amount of play AX is added to the length of the major axis of the ellipse, and the value obtained by addition is multiplied by 1.2 to obtain a first value. Or, the amount of play ΔX is added to the length of the minor axis of the ellipse, and the value obtained by addition is multiplied by 1.2 to obtain a second value. The elliptical shutter 64 need only have a major axis whose length is equal to or larger than the first value or a minor axis whose length is equal to or larger than the second value.

When the shutter 64 is square, a minimal square including the estimated plane is set, the amount of play ΔX is added to the length of a side of the square, and the value obtained by addition is multiplied by 1.2. The square shutter 64 need only have a one side whose length is equal to or larger than the resulting value.

Further, when the shutter 64 is rectangular, a minimal rectangle including the estimated plane is set, the amount of play ΔX is added to the length of a longer side of the rectangle, and the value obtained by addition is multiplied by 1.2 to obtain a first value. Or, the amount of play ΔX is added to the length of a shorter side of the rectangle, and the value obtained by addition is multiplied by 1.2 to obtain a second value. The rectangular shutter 64 need only have a longer side whose length is equal to or larger than the first value or a shorter side whose length is equal to or larger than the second value.

When one shutter 64 is used for plural evaporators 31 in the evaporating unit 32, provisional estimated planes are detected for the respective evaporators and a minimal circle or rectangle including the provisional estimated planes of all the evaporators is assumed to be the estimated plane, which is as described above.

Alternatively, a maximal length Lmax of the estimated plane is detected, the amount of play ΔX is added to the maximal length, the value obtained by addition is then multiplied by 1.2 to obtain a value Wmax. The shutter 64 having a length W which is equal to or larger than the value Wmax for the whole area may be provided.

In other words, in this case, the shutter 64 has a diameter W which is equal to or larger than Wmax in a circular shape, a one-side length W which is equal to or larger than Wmax in a square shape, and a shorter-side length W which is equal to or larger than Wmax in a rectangular shape.

A pretreatment for melting film forming materials prior to the film formation by vacuum deposition is generally carried out under the conditions identical or similar to the film forming conditions.

When vacuum deposition is carried out at an usual degree of vacuum, evaporated particles moves upward. Therefore, the shutter can block the evaporated particles generated during the pretreatment, if the size of the shutter is determined so that the shutter may have the same size as that of the estimated plane (optionally including the amount of play ΔX).

However, as described above, particles such as argon particles float in the vacuum deposition system under medium vacuum (0.05 to 10 Pa) as in the present invention. Therefore, the substrate S must be brought into close proximity to the evaporators 31 in the evaporating unit 32. In addition, the evaporated particles collide with the floating particles and are diffused in a manner like Brownian motion. Therefore, if the size of the shutter is determined depending on the estimated plane, the evaporated particles pass along the shutter during the pretreatment to reach the substrate S to which the evaporated particles adhere.

In this embodiment, the value obtained by multiplying the sum of the size of the estimated plane at the blocking position and the amount of play ΔX in the surface direction of the substrate S at the blocking position of the shutter 64 by 1.2 is assumed to be the size of the shutter 64 to handle the vacuum deposition under medium vacuum. Particles evaporated from the evaporating unit 32 (evaporator or evaporators 31) are prevented from reaching the rear surface of the shutter 64 and adhering to the substrate S by providing the shutter 64 slightly larger than the area in which the evaporated particles can flow and diffuse from the the evaporating unit 32 (evaporator or evaporators 31) during the pretreatment.

Therefore, if the volume of the vacuum deposition device 10 can be made large, that is, there is no obstacle when the large shutter is opened or closed, a numeral value of 1.2 or more is preferably chosen. In fact, when the volume of the device is made large, the volume of an exhauster becomes large, thereby boosting the cost and reducing the evaporation throughput. Consequently, this numerical value is preferably in the range of 1.2 to 3.0.

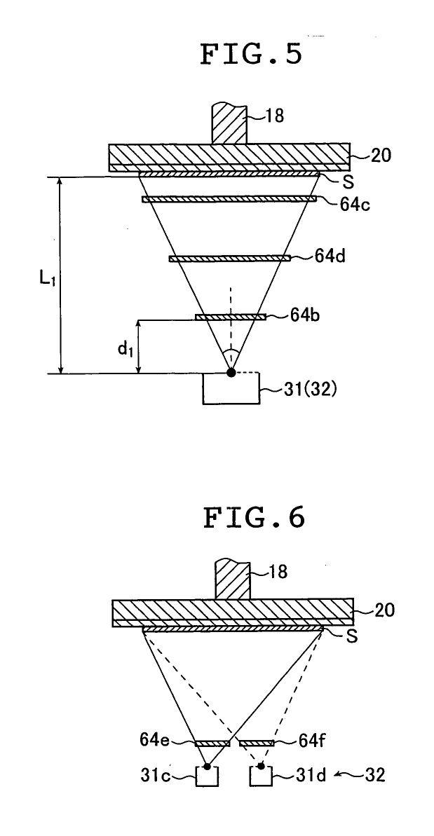

A plurality of shutters 64 may be interposed between the evaporating unit 32 (evaporator or evaporators 31) and the substrate S. For example, as shown in FIG. 5 which illustrates a first modification of the present invention, a plurality of shutters 64b, 64c, and 64d are installed parallel to the surface of the substrate S and between the evaporator 31 and the substrate S at positions where they overlap one another when seen from the normal direction of the surface of the substrate S. In this case, each of the shutters 64b, 64c, and 64d must satisfy the above expression (1) and/or the expression (2). As will be described hereinafter, the provision of two shutters 64b and 64c is particularly effective and preferred in such a manner that one shutter 64b is installed close to the evaporator 31 and the other shutter 64c is installed close to the substrate S.

In the above vacuum deposition device, when the plurality of evaporators are arranged on a plane parallel to the substrate S, each shutter is installed on a plane parallel to the surface of the substrate. In another embodiment of the present invention, shutters may be provided corresponding to a plurality of evaporators. For example, as shown in FIG. 6 illustrating a second modification of the present invention, it is possible that two evaporators 31c and 31d be installed in a direction parallel to the surface of the substrate S below the substrate S in the figure and shutters 64e and 64f be provided for the evaporators 31c and 31d, respectively. In this case, each of the shutters 64e and 64f must satisfy the above expression (1) and/or the expression (2). Further, in proximity to the evaporation sources, shutters may be provided to cover the respective evaporation sources and in proximity to the substrate, a single shutter may be provided to cover the entire substrate S. In this case, each of the shutters must satisfy the above expression (1) and/or the expression (2).

A more detailed description is given of a pretreatment method before a phosphor film is formed when the phosphor film is formed by using the vacuum deposition device 10 of this embodiment. As described above, the vacuum deposition device 10 according to this embodiment carries out two-source vacuum deposition by introducing a gas for resistance heating. To produce a phosphor sheet by using this vacuum deposition device 10, a pretreatment is carried out before the formation of a phosphor film.

To carry out the pretreatment according to this embodiment, the substrate S is mounted on the undersurface of the turntable 20 at a predetermined position with the film forming surface facing down, the vacuum chamber 12 is closed to reduce the internal pressure, and the substrate S is heated from its rear surface with a sheathed heater 24.

When the degree of vacuum in the system of the vacuum deposition device 10 reaches a predetermined value, the shutter 64 is closed, that is, the shutter 64 is stopped at a blocking position, and an inert gas such as Ar gas is introduced into the vacuum chamber 12 to reduce the internal pressure of the vacuum deposition device 10 to a predetermined medium degree of vacuum (e.g., about 0.1 Pa). After the internal pressure of the vacuum chamber 12 becomes a predetermined degree of vacuum, the resistance heater 34 of the Eu evaporator 31b of the heating evaporating section 16 is activated to heat/melt europium bromide (EuBr₂) in the evaporation position (crucible) and the resistance heater 36 of the Cs evaporator 31a is activated to heat/melt cesium bromide (CsBr) in the evaporation position.

In the case of deposition by resistance heating, a current is applied to the resistance heaters to heat the evaporators. The main component, activator component, and the like of the stimulable phosphor in the evaporators are heated to be molten. After the pretreatment is over with the molten components in the evaporators, the turntable 20 is turned at a predetermined speed by the rotation drive source 18. That is, the formation of the phosphor film is started in the heating evaporating section 16 while the substrate S is turned at a predetermined speed.

Stated more specifically, in the heating evaporating section 16, the shutter 64 is opened as shown by a dotted line in FIG. 1 and the resistance heater 34 of the Eu evaporator 31b is heated to evaporate europium bromide (EuBr₂) in the evaporation position (crucible). In addition, the resistance heater 36 of the Cs evaporator 31a is driven to evaporate cesium bromide (CsBr) in the evaporation position similarly to start the deposition of CsBr:Eu on the glass substrate S, that is, the formation of a phosphor film of interest.

Any known method used in various vacuum deposition devices can be used to open the shutter 64.

The main component, activator component, and the like of the stimulable phosphor in the evaporators are heated to be evaporated and diffused. A reaction between them occurs to form a phosphor which is then deposited on the surface of the substrate S. To carry out deposition by introducing an inert gas as in this embodiment, use of the resistance heater is preferred.

Since the Eu evaporator 31b and the Cs evaporator 31a are arranged close to each other as described above, a mixed vapor of film forming materials containing a vapor of an extremely trace amount of europium bromide (EuBr₂) dispersed therein uniformly is formed near the heating evaporating section 16, and CsBr:Eu containing the activator dispersed therein uniformly is deposited with this mixed vapor.

After the formation of a film having a predetermined thickness is over, the revolution of the turntable 20 is stopped, and the vacuum state of the vacuum chamber 12 is released to take out the substrate S on which the phosphor film has been formed. To carry out film formation continuously, after a new substrate S is set likewise and a pretreatment is made, film formation may be carried out.

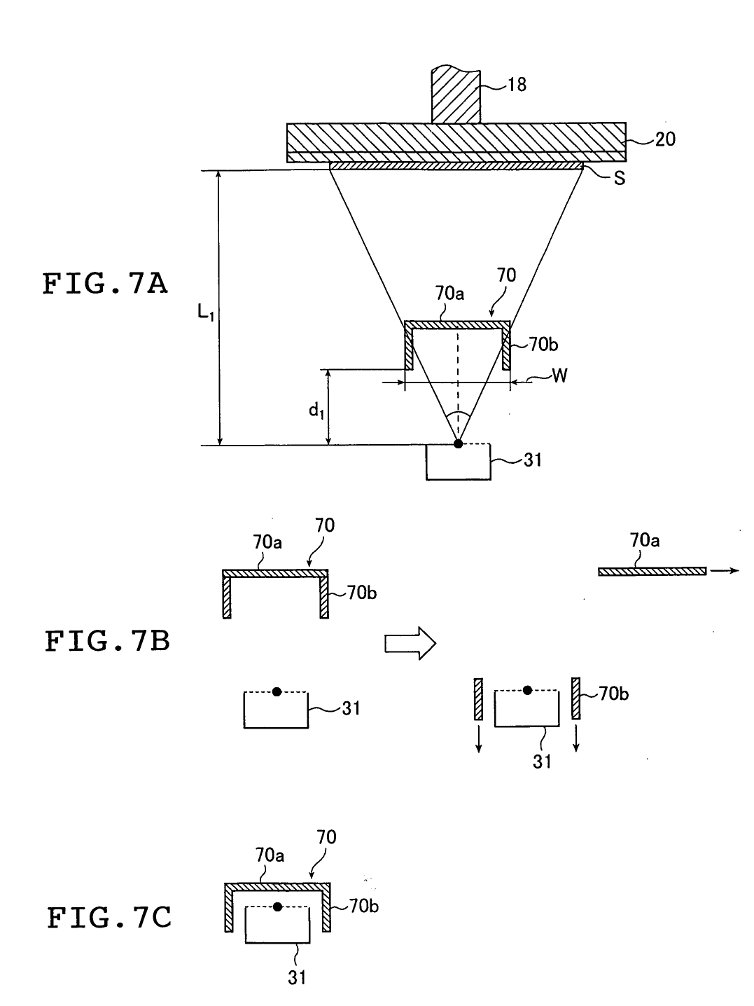

The shutter 64 used in the above embodiment has a plate shape, but this is not the sole case of the present invention. As shown in FIG. 7A, a shutter 70 which has a planar plate 70a and wall portions 70b protruding from the planar plate 70a downward (usually in the direction perpendicularly crossing the planar plate 70a) and formed so as to surround the inside of the shutter 64 is advantageously used.

Assuming that the lower ends of the wall portions 70b are positioned on the estimated plane (virtual shutter surface) as schematically shown in FIG. 7A, the distance between the lower ends in the shutter 70 need only have a length W satisfying the expression (1).

The shutter 70 having the wall portions 70b can prevent evaporated particles of the film forming materials from being diffused in the horizontal direction, so that the evaporated particles can be more advantageously prevented from reaching the rear surface of the shutter during the pretreatment and hence adhering to the substrate S.

Since the lower ends of the wall portions 70b can be positioned on the estimated plane as described above, the planar plate 70a (ceiling surface) which actually blocks the evaporated particles can be set at a higher position than the plate-shaped shutter 64, whereby adhesion of the evaporated particles to the shutter 70 can also be reduced. In addition, since the length W can be set assuming that the lower ends of the wall portions 70b are positioned on the estimated plane, the area of the planar plate 70a can be more reduced than the plate-shaped shutter 64 taking the position of the planar plate 70a into consideration, leading to the downsizing of the shutter 70 and the improvement of the degree of design flexibility in the moving direction/method or the like.

There is no particular limitation on the height of the wall portions 70b. The higher the wall portions 70b are, the more the effects (size reduction in the surface direction and prevention of adhesion of evaporated particles to the shutter 70) are increased. However, constraints due to the size of the shutter in the height direction are increased. Therefore, the height of the wall portions 70b are appropriately determined in accordance with the device configuration and size.

When the shutter 70 having the planar plate 70a and the wall portions 70b protruding downward from the planar plate 70a is used, a configuration is illustrated in which the whole of the planar plate 70a and the wall portions 70b are moved as a unit to switch from closed state to open state.

Alternatively, another configuration as shown in FIG. 7B is also advantageously used in which the planar plate 70a and the wall portions 70b are formed separately and the shutter 70 is switched from closed state to open state by moving the planar plate 70a in the surface direction of the substrate S while the wall portions 70b are moved downward.

When the shutter 70 having the wall portions 70b protruding downward from the planar plate 70a is used, it is also possible to completely cover the evaporator 31 as shown in FIG. 7C by lowering the lower ends of the wall portions 70b below the evaporation position when the shutter 70 is closed. In this case, since the lower ends of the wall portions 70b are positioned below the evaporation position, the maximal length of the estimated plane is zero.

The operation for closing or opening the evaporator 31 by the shutter 70 can be readily carried out in the configuration shown in FIG. 7B in which the planar plate 70a and the wall portions 70b are formed separately.

In the above examples, a shutter (blocking member) is used as prevention means for preventing the adhesion of evaporated particles to the substrate S in the vacuum deposition under medium vacuum. However, in another embodiment of the present invention, sealing means for positioning the substrate S in a space airtightly separated from a space where the evaporating unit 32 (evaporator or evaporators 31) is provided is used as the prevention means.

The evaporated particles can be thus prevented from adhering to the substrate S during the pretreatment by carrying out the pretreatment with the substrate S and the evaporating unit 32 (evaporator or evaporators 31) being positioned in different spaces.

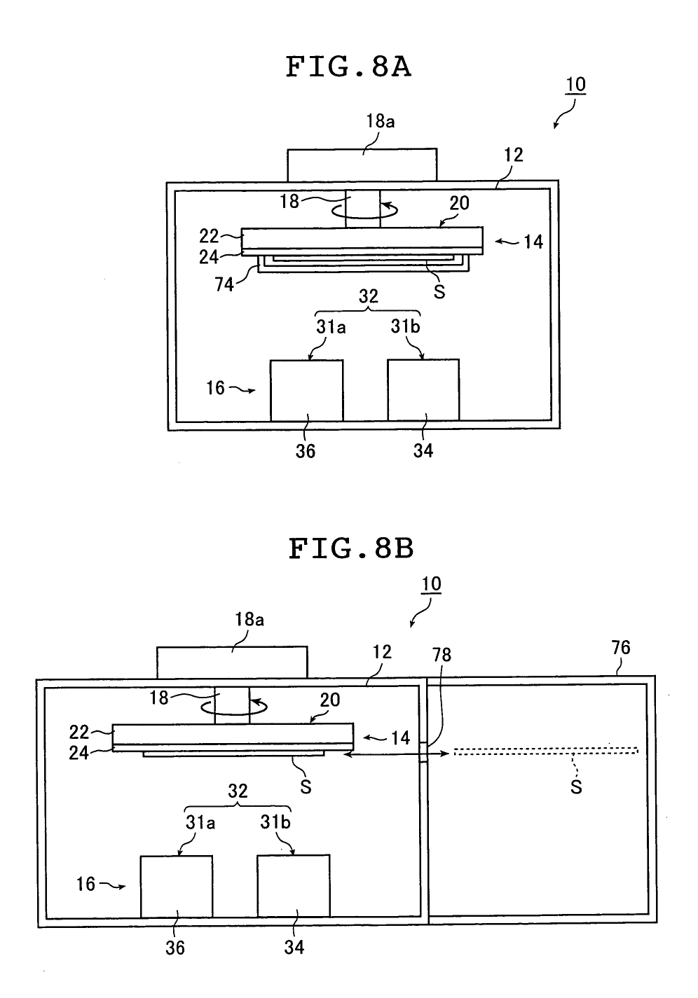

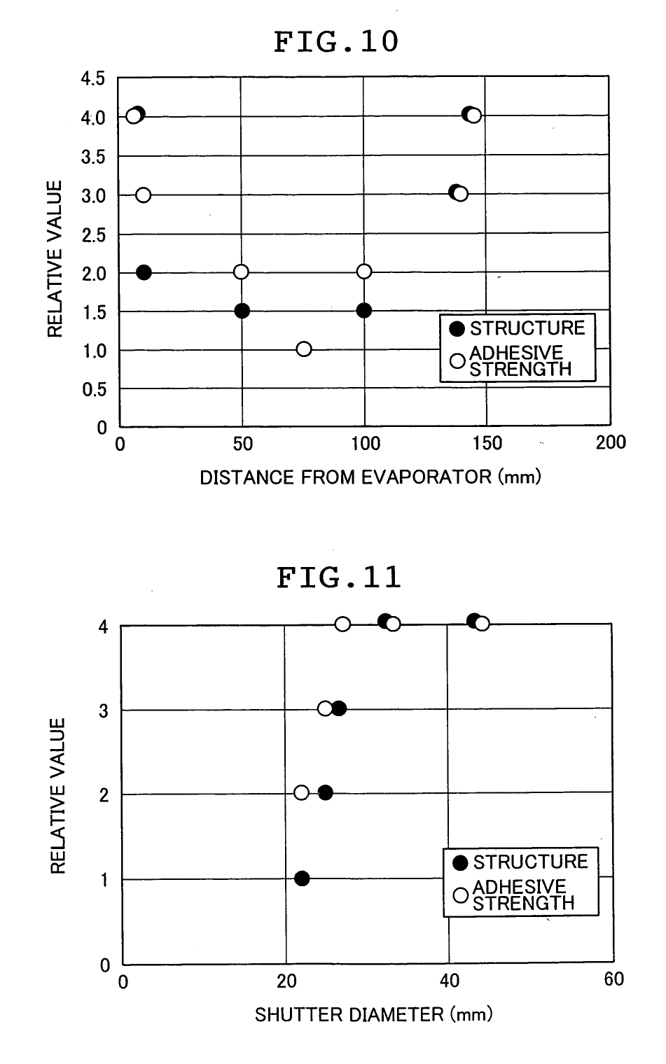

A method shown in FIG. 8A is illustrated in which a case-shaped cover member 74 whose open surface side is brought into contact with the sheathed heater 24 during the pretreatment to airtightly enclose the substrate S is used as the sealing means. Alternatively, a cover member which includes the substrate holding and rotating mechanism 14 and is brought into contact with the inner wall of the vacuum chamber 12 to airtightly enclose the substrate S may be used instead.

There is no particular limitation on the moving means of the cover member 74 for closing or opening the substrate S, and various known means can be used.

Another method as shown in FIG. 8B is also available in which a sub-chamber 76 communicating with the vacuum chamber 12 and a shutter 78 for airtightly closing or opening a communicating portion between the vacuum chamber 12 and the sub-chamber 76 are provided to form the sealing means. In this case, during the pretreatment, the substrate S is retreated from the vacuum chamber 12 to the sub-chamber (retreat chamber) 76 and held in the sub-chamber 76 and the shutter 78 is closed. When the film formation is started after the end of the pretreatment, the shutter 78 is opened to move the substrate S from the sub-chamber 76 to the vacuum chamber 12, where the substrate S is mounted on the substrate holding and rotating mechanism 14 (on the surface of the sheathed heater 24). The shutter 78 is then closed.

Any known method for moving and holding a sheet member can be used to move the substrate S to the holding and rotating mechanism 14 and to hold the substrate S thereon.

In addition, according to still another embodiment of the present invention, means for moving the substrate S away from the evaporating unit 32 (evaporator or evaporators 31) is used as the prevention means for preventing the evaporated particles from adhering to the substrate S in the vacuum deposition under medium vacuum.

The evaporated particles can also be thus prevented from adhering to the substrate S during the pretreatment by carrying out the pretreatment with the substrate S being moved away from the evaporating unit 32 (evaporator or evaporators 31).

A method is illustrated in which the ceiling of the vacuum chamber 12 is heightened and the rotary shaft 18 which is made vertically movable is moved upward to move the turntable 20 upward to thereby locate the substrate S away from the evaporating unit 32 (evaporator or evaporators 31). Alternatively, any known sheet member moving method may be used to move the substrate S in the substrate surface direction (horizontal direction) to thereby locate the substrate S away from the evaporating unit 32 (evaporator or evaporators 31).

In this practice, the distance between the substrate S to be moved away and the evaporating unit 32 (evaporator or evaporators 31) can be appropriately determined based on the film forming conditions (pretreatment conditions). The distance is preferably about lm.

The above embodiments are all applied to the vacuum deposition device of substrate rotation type, but this is not the sole case of the present invention. A device which carries out vacuum deposition while linearly transporting the substrate S as conceptually shown in a plan view of FIG. 9 may be used.

In this case, the substrate S may be transported only in one direction but linear to-and-fro motion of the substrate is preferably performed several times to form a phosphor film having a uniform and sufficient thickness. Any known method for holding and transporting a sheet member can be used for the linear transport and to-and-fro motion of the substrate.

One set of the evaporators 31 (one Cs evaporator 31a and one Eu evaporator 31b) in the evaporating unit 32 suffices to linearly transport the substrate S. However, it is preferable to arrange plural set of the evaporators 31 (in the illustrated case, six set of the evaporators 31 having six Cs and Eu evaporators 31a and 31b, respectively) in a direction perpendicular to the direction in which the substrate S is transported. A phosphor film having a uniform film thickness can be formed by arranging the evaporators 31 in the direction perpendicular to the substrate transporting direction and carrying out vacuum deposition while transporting the substrate S in a to-and-fro manner.

The embodiment shown in FIG. 9 has a line of the Cs evaporators 31a and a line of the Eu evaporators 31b, respectively. However, this is not the sole case of the present invention. One line may be formed for the Eu evaporators 31b whose deposition amount is small and two lines for the Cs evaporators 31a. Alternatively, more than one line may be formed for both the evaporators 31a and 31b. In the last case, the number of lines for the Cs and Eu evaporators 31a and 31b may be the same or different.

When a large number of evaporators 31 in the evaporating unit 32 are arranged, or even when plural lines of evaporators 31 are arranged, the length W of the shutter 64 can be determined by the same method as described above. In addition, when one shutter 64 is used for plural evaporators 31, provisional estimated planes are detected for the respective evaporators and a minimal circle or rectangle including the provisional estimated planes of all the evaporators is assumed to be the estimated plane for the shutter 64, which is as described above.

In the case of linear transport of the substrate S, the estimated plane can be set with respect to the position of the substrate S during the pretreatment. For example, if the substrate S during the pretreatment is in a position shown by a solid line in FIG. 9, the estimated plane is set based on this position and each evaporator 31, the length W is then set by the method described above and a shutter 64 satisfying the set length is mounted.

The following examples are given to further illustrate the present invention.

### EXAMPLES

One-source vacuum deposition, that is, one evaporator 31 in the evaporating unit 32 was used as shown in FIG. 3A, the evaporation conditions of the film forming materials were fixed, and the size and position of the shutter 64 were changed to compare the formed phosphor films in terms of adhesive strength and image characteristics (degree of structure).

Evaporator:

Cesium bromide (CsBr) powder having a purity of 4N or more and europium bromide (EuBr₂) powder having a purity of 3N or more were prepared in an evaporator. When the trace elements in each powder were analyzed by means of ICP-MS (inductively coupled plasma spectrometry-mass spectrometry), the amounts of alkali metals (Li, Na, K, Rb) other than Cs in CsBr were each 10 ppm or less and the amounts of other elements such as alkali earth metals (Mg, Ca, Sr, Ba) were 2 ppm or less. The amounts of rare earth elements other than Eu in EuBrₓ were each 20 ppm or less and the amounts of other elements were each 10 ppm or less. The evaporator was installed right below the rotary shaft 18 of the turntable 20.

Shutter:

In an experiment (experiment 1) in which the diameter of the shutter was changed, five different metal shutters having a diameter of about 20 to 50 mm were used and set right above the opening of the evaporator to form a phosphor film. The experiment was carried out while the distance between the evaporator and the shutter was 10 mm.

In an experiment (experiment 2) in which the position of the shutter was changed, a metal shutter having a diameter of 25 mm was used and set right above the opening of the evaporator to form a phosphor film. The distance between the evaporator and the shutter was changed to seven values: near the evaporator, about 50 mm, about 75 mm, and about 100 mm from the evaporator, and near the substrate S. Formation of phosphor film:

A synthetic quartz substrate S which had been cleaned with an alkali, pure water, and IPA (isopropyl alcohol) in this order was prepared as a support and set on a substrate S holder in the deposition device. CsBr and EuBr₂ as film forming materials were filled into the evaporator shown in the above embodiment and the internal pressure of the device was set at 1×10⁻³ Pa. After that, Ar gas was introduced into the device to reduce the inside degree of vacuum to 1.0 Pa. Before deposition, the shutter 64 was stopped at the blocking position to close the opening of the evaporator and the resistance heater 34 was activated to melt the evaporator stored in the evaporation position (crucible) so as to carry out a pretreatment. After that, the substrate S was heated at 100° C. with the sheathed heater to carry out deposition. The distance between the substrate S and the evaporator was maintained at 150 mm to deposit a CsBr:Eu stimulable phosphor on the substrate S at a rate of 5 μm/minute. By controlling a current to each heater, the molar ratio of Eu to Cs in the stimulable phosphor was adjusted to 0.003/1.

As for the use of the shutter, an experiment (experiment 1) in which five shutters having different diameters were used was conducted and then an experiment (experiment 2) in which the distance between the evaporator and the shutter was changed was conducted. The measurements of those two experiments were compared with each other. The results are shown in FIG. 7 and FIG. 8.

FIG. 7 is a graph showing the relationship between the distance between the evaporator and the shutter and the characteristic properties of the phosphor film deposited on the surface of the substrate S. The distance between the evaporator and the shutter is plotted on the horizontal axis and the relative value which is an index of the characteristic properties of the phosphor film is plotted on the vertical axis.

FIG. 8 is a graph showing the relationship between the size (diameter) of the shutter and the characteristic properties of the phosphor film deposited on the surface of the substrate S. The size (diameter) of the shutter is plotted on the horizontal axis and the relative value which is an index of the characteristic properties of the phosphor film is plotted on the vertical axis.

The relative values shown on the vertical axes of the graphs of FIG. 7 and FIG. 8 are the results of judgment on whether the phosphor film peels off or not when four different tapes having different adhesive strengths are affixed to a phosphor film formed on the surface of the substrate S and are removed, and the values show the adhesive strength of the tape when the phosphor film peels off. The relative value of “0” means that the phosphor film already peels off before the tape is affixed. Therefore, as the relative value becomes larger, the adhesive strength of the phosphor film becomes higher.

As for structure out of the points shown on the graphs of FIG. 7 and FIG. 8, the relative values on the vertical axes show the degrees of image nonuniformity when an X-ray image is recorded using a radiation image converting panel obtained by forming a phosphor film on the surface of the substrate S. As the relative value becomes smaller, the image nonuniformity becomes higher and as the relative value becomes larger, the image nonuniformity becomes lower, that is, the image has higher quality. The relationship between the relative value and the image nonuniformity is shown below.

Relative Value Image Quality

4 no image nonuniformity which can be observed
3 permissible image nonuniformity is observed
2 impermissible image nonuniformity is observed
1 totally impermissible image nonuniformity is observed

As shown in the graph of FIG. 8, when the shutter diameter becomes 20 to 30 mm, the relative value sharply increases. That is, both the adhesive strength and structure sharply rise. When the shutter diameter becomes 30 to 40 nm, an increase in the relative value slows down. That is, increases in both the adhesive strength and the structure slow down and the adhesive strength and the structure become almost a constant value. The above results indicate that the optimum value of the shutter diameter may be around 30 mm under the conditions of this embodiment.

As shown in the graph of FIG. 7, when the distance between the evaporator and the shutter is 0 to 50 mm, as the distance becomes shorter, the relative value becomes larger. When the distance between the evaporator and the shutter is 100 to 150 mm, as the distance between the evaporator and the shutter becomes longer, the relative value becomes larger. That is, as the distance between the shutter and the substrate S becomes shorter, the relative value becomes larger. It is understood from the above results that when the shutter is at a position close to the evaporator or the substrate S, the relative value, that is, the characteristic properties of the phosphor film improve. The results of the graph shown in FIG. 7 show that when two shutters are installed at a position close to the evaporator and at a position close to the substrate S, the characteristic properties of the phosphor film improve.

According to the vacuum deposition device 10 of this embodiment, the shutter 64 having a predetermined size, that is, a size that satisfies the relationship of the expression (1) mentioned earlier is installed at a predetermined position, that is, a position apart from the evaporating unit 32 (evaporator or evaporators 31) by a distance equal to or shorter than the mean free path of film forming material particles at a pretreatment pressure. Therefore, the particles of the film forming materials from the evaporator do not move and reach the rear surface (surface opposite to the substrate S) of the shutter 64 during the pretreatment. As a result, the adhesion of the particles of the film forming materials to the surface of the substrate S by the pretreatment is prevented and a phosphor sheet having uniform X-ray characteristics and high quality can be manufactured.

1. A vacuum deposition device, comprising:
a vacuum deposition chamber;
vacuum evacuation means for evacuating an inside of said vacuum deposition chamber;
an evaporating unit for evaporating one or more film forming materials, said evaporating unit being provided in said vacuum deposition chamber;
a holding unit for holding a substrate on which said one or more film forming materials are deposited, said holding unit being provided above said evaporating unit; and
prevention means for preventing evaporated particles of said one or more film forming materials from adhering to said substrate held by said holding unit when vacuum deposition is carried out at a pressure of 0.05 to 10 Pa.

2. The vacuum deposition device according to claim 1,
wherein said prevention means comprises a blocking member which is interposed between said evaporating unit and said holding unit so as to be movable between an opening position for opening an upper area located above said evaporating unit in said vacuum deposition chamber and a blocking position for blocking said upper area above said evaporating unit and which stops at said blocking position to block vapor flows of said one or more film forming materials flowing from said evaporating unit to said substrate, and
wherein said blocking member has a length W in a surface direction of said substrate which satisfies an expression (1):
W≧1.2×(length on an estimated plane+ΔX) (1)
wherein an estimated plane denotes a section obtained by cutting a cone whose bottom is a surface of said substrate and whose height is a distance between said evaporating unit and said substrate with a plane passing through a position at which said blocking member is provided and being parallel to said bottom of said cone, and ΔX denotes an amount of play in said surface direction of said substrate at said blocking position of said blocking member.

3. The vacuum deposition device according to claim 1,
wherein said prevention means comprises a blocking member which is interposed between said evaporating unit and said holding unit so as to be movable between an opening position for opening an upper area located above said evaporating unit in said vacuum deposition chamber and a blocking position for blocking said upper area above said evaporating unit and which stops at said blocking position to block vapor flows of said one or more film forming materials flowing from said evaporating unit to said substrate, and
wherein said blocking member is variably provided at a position apart from one of said evaporating unit and said substrate by a distance d which satisfies an expression (2):
d≦M (2)
wherein M denotes a mean free path of said evaporated particles of said one or more film forming materials at a pretreatment pressure in said vacuum deposition.

4. The vacuum deposition device according to claim 1,
wherein said prevention means comprises a blocking member which is interposed between said evaporating unit and said holding unit so as to be movable between an opening position for opening an upper area located above said evaporating unit in said vacuum deposition chamber and a blocking position for blocking said upper area above said evaporating unit and which stops at said blocking position to block vapor flows of said one or more film forming materials flowing from said evaporating unit to said substrate,
wherein said blocking member has a length W in a surface direction of said substrate which satisfies an expression (1):
W≧1.2×(length on an estimated plane+ΔX) (1)
wherein an estimated plane denotes a section obtained by cutting a cone whose bottom is a surface of said substrate and whose height is a distance between said evaporating unit and said substrate with a plane passing through a position at which said blocking member is provided and being parallel to said bottom of said cone, and AX denotes an amount of play in said surface direction of said substrate at said blocking position of said blocking member, and
wherein said blocking member is variably provided at a position apart from one of said evaporating unit and said substrate by a distance d which satisfies an expression (2):
d≦M (2)
wherein M denotes a mean free path of said evaporated particles of said one or more film forming materials at a pretreatment pressure in said vacuum deposition.

5. The vacuum deposition device according to claim 2, wherein said blocking member includes a plate-shaped portion facing said evaporating unit and one or more wall portions protruding downward from said plate-shaped portion.

6. The vacuum deposition device according to claim 2, wherein said prevention means further comprises one or more blocking members interposed between said evaporating unit and said substrate, and said blocking member and said one or more blocking members overlap each other when seen from a normal direction of the surface of said substrate.

7. The vacuum deposition device according to claim 2, wherein said evaporating unit has two or more evaporators which are installed beside each other in said surface direction of said substrate in said vacuum deposition chamber, and said prevention means further comprises one or more blocking members interposed between said evaporating unit and said substrate such that each blocking member is provided for each evaporator.

8. The vacuum deposition device according to claim 2, wherein said evaporating unit has two or more evaporators, and said blocking member is provided in one plane parallel to said surface of said substrate for said two or more evaporation sources such that said blocking member covers all of said two or more evaporators.

9. The vacuum deposition device according to claim 1, wherein said prevention means is separation means for locating said substrate in a space airtightly separated from a space where said evaporating unit exists.

10. The vacuum deposition device according to claim 9, wherein said separation means is a cover for airtightly enclosing said substrate held by said holding unit.

11. The vacuum deposition device according to claim 9, wherein said separation means includes a retreat chamber communicating with said vacuum deposition chamber, closing means for airtightly closing a communicating portion between said vacuum deposition chamber and said retreat chamber, and moving means for moving said substrate between said holding unit in said vacuum deposition chamber and said retreat chamber.

12. The vacuum deposition device according to claim 1, wherein said prevention means is means for moving said substrate away from said evaporating unit.

13. The vacuum deposition device according to claim 1, wherein a distance between said evaporating unit and said substrate held by said holding unit is 100 to 300 mm.

14. A pretreatment method for vacuum deposition comprising the step of:
preparing prevention means for preventing evaporated particles of one or more film forming materials from adhering to a substrate on which said one or more film forming materials are deposited in a vacuum deposition chamber; and
melting said one or more film forming materials by heating in said vacuum deposition chamber at a pressure of 0.05 to 10 Pa while preventing said evaporated particles from adhering to said substrate for the vacuum deposition by using said prevention means.

15. The pretreatment method according to claim 14,
wherein said prevention means is a blocking member which is interposed between an evaporating unit which evaporates said one or more film forming materials and is provided in said vacuum deposition chamber and a holding unit which holds said substrate and is provided above said evaporating unit so as to be movable between an opening position for opening an upper area located above said evaporating unit in said vacuum deposition chamber and a blocking position for blocking said upper area above said evaporating unit and which stops at said blocking position to block vapor flows of said one or more film forming materials flowing from said evaporating unit to said substrate, and
wherein said blocking member has a length W in a surface direction of said substrate which satisfies an expression (1):
W≧1.2×(length on an estimated plane+ΔX) (1)
wherein an estimated plane denotes a section obtained by cutting a cone whose bottom is a surface of said substrate and whose height is a distance between said evaporating unit and said substrate with a plane passing through a position at which said blocking member is provided and being parallel to said bottom of said cone, and ΔX denotes an amount of play in said surface direction of said substrate at said blocking position of said blocking member.

16. The pretreatment method according to claim 14,
wherein said prevention means is a blocking member which is interposed between an evaporating unit which evaporates said one or more film forming materials and is provided in said vacuum deposition chamber and a holding unit which holds said substrate and is provided above said evaporating unit so as to be movable between an opening position for opening an upper area located above said evaporating unit in said vacuum deposition chamber and a blocking position for blocking said upper area above said evaporating unit and which stops at said blocking position to block vapor flows of said one or more film forming materials flowing from said evaporating unit to said substrate, and
wherein said blocking member is variably provided at a position apart from one of said evaporating unit and said substrate by a distance d which satisfies an expression (2):
d≦M (2)
wherein M denotes a mean free path of said evaporated particles of said one or more film forming materials at a pretreatment pressure in said vacuum deposition.

17. The pretreatment method according to claim 14,
wherein said prevention means is a blocking member which is interposed between an evaporating unit which evaporates said one or more film forming materials and is provided in said vacuum deposition chamber and a holding unit which holds said substrate and is provided above said evaporating unit so as to be movable between an opening position for opening an upper area located above said evaporating unit in said vacuum deposition chamber and a blocking position for blocking said upper area above said evaporating unit and which stops at said blocking position to block vapor flows of said one or more film forming materials flowing from said evaporating unit to said substrate, and
wherein said blocking member has a length W in a surface direction of said substrate which satisfies an expression (1):
W≧1.2×(length on an estimated plane+ΔX) (1)
wherein an estimated plane denotes a section obtained by cutting a cone whose bottom is a surface of said substrate and whose height is a distance between said evaporating unit and said substrate with a plane passing through a position at which said blocking member is provided and being parallel to said bottom of said cone, and ΔX denotes an amount of play in said surface direction of said substrate at said blocking position of said blocking member, and
wherein said blocking member is variably provided at a position apart from one of said evaporating unit and said substrate by a distance d which satisfies an expression (2):
d≦M (2)
wherein M denotes a mean free path of said evaporated particles of said one or more film forming materials at a pretreatment pressure in said vacuum deposition.

18. The pretreatment method according to claim 15, wherein said blocking member includes a plate-shaped portion facing said evaporating unit and one or more wall portions protruding downward from said plate-shaped portion.

19. The pretreatment method according to claim 15, wherein said prevention means further comprises one or more blocking members interposed between said evaporating unit and said substrate, and said blocking member and said one or more blocking members overlap each other when seen from a normal direction of the surface of said substrate.

20. The pretreatment method according to claim 15, wherein said evaporating unit has two or more evaporators containing at least two evaporators for CsBr and EuBr₂, which are provided on respective predetermined planes parallel to said surface of said substrate in said vacuum deposition chamber, and said prevention means further comprises one or more blocking members interposed between said evaporating unit and said substrate such that each blocking member is provided for each evaporator. wherein two or more evaporating units containing at least CsBr and EuBr₂ are provided on respective predetermined planes parallel to the surface of the substrate in the vacuum deposition chamber and the blocking member is provided for each of the evaporating units.

21. The pretreatment method according to claim 15, wherein said evaporating unit has two or more evaporators containing at least two evaporators for CsBr and EuBr₂, and said blocking member is provided in one plane parallel to said surface of said substrate for said two or more evaporation sources such that said blocking member covers all of said two or more evaporators.

22. The pretreatment method according to claim 14, wherein said prevention means is separation means for locating said substrate in a space airtightly separated from a space where said evaporating unit exists.

23. The pretreatment method according to claim 22, wherein said separation means is a cover for airtightly enclosing said substrate held by said holding unit.

24. The pretreatment method according to claim 22, wherein said separation means includes a retreat chamber communicating with said vacuum deposition chamber, closing means for airtightly closing a communicating portion between said vacuum deposition chamber and said retreat chamber, and moving means for moving said substrate between said holding unit in said vacuum deposition chamber and said retreat chamber.

25. The pretreatment method according to claim 14, wherein said prevention means is means for moving said substrate away from said evaporating unit.

26. The pretreatment method according to claim 14, wherein a distance between said evaporating unit and said substrate held by said holding unit is 100 to 300 mm.
